(19) United States
(12) Patent Application Publication
(10) Pub. No.: US 2004/0017252 A1
(43) Pub. Date: Jan. 29, 2004

(54) Current chopper-type D class power amplifier

(76) Inventor: Katsumi Miyazaki, Hyogo (JP)

Correspondence Address: BURNS, DOANE, SWECKER & MATHIS, L.L.P., P.O. Box 1404, Alexandria, VA, 22313-1404, US

(21) Appl. No.: 10/334,001

(22) Filed: Dec. 31, 2002

(30) Foreign Application Priority Data
Jul. 24, 2002 (JP) 2002-215179 (P)

(51) Int. Cl. H03F 3/38

(52) U.S. Cl. 330/10

(57) ABSTRACT

An output current fed to a load is controlled by a full bridge formed with first to fourth transistors. First and second mirror transistors provided to form current mirrors with transistors forming the full bridge, and first and second detection resistances respectively connected to the first and second mirror transistors in series are provided. Operations of the full bridge are controlled corresponding to detection voltages at the first and second detection resistances. Further, on-off switching of transistors belonging to one side of the bridge is controlled corresponding to voltage drop at the detection resistance provided corresponding to the other side of the bridge.

### BACKGROUND OF THE INVENTION

1. Field of the Invention

The present invention relates to a power amplifier and, more specifically, to a power amplifier which is a class D amplifier of a current chopper-type pulse width modulation (PWM) system.

2. Description of the Background Art

A current chopper-type class D amplifier is known as a power amplifier to feed a direct current to a load. The current chopper-type class D amplifier is characterized by good linearity of input-output transfer conductance, because it directly detects a load current and performs a feedback control based on the detected load current. The current chopper-type class D amplifier is generally used for controlling current feed to an inductive load, wherein the linearity of transfer conductance is particularly considered more important than linearity of a voltage gain.

FIG. 6 is a circuit diagram showing a power amplifier configuration of a current chopper-type class D amplifier according to a prior art.

Referring to FIG. 6, a power amplifier 100 according to a prior art feeds an output current Io to a load 105 connected between output nodes No and /No. Output current Io is controlled corresponding to a voltage difference between an input voltage VIN input to an input voltage terminal 106 and a reference voltage VREF input to a reference voltage terminal 107. While reference voltage VREF is fixed, input voltage VIN is set to a level corresponding to a desired value of output current Io. More specifically, output current Io is fed in a direction from output node No toward /No (positive direction) when VIN>VREF (also referred to as “positive direction command time” hereafter), and is fed in a direction from output node /No toward No (negative direction) when VIN<VREF (also referred to as “negative direction command time” hereafter). Magnitude of output current Io is controlled corresponding to |VIN−VREF|.

Power amplifier 100 includes transistors 110a, 110b, 120a, 120b forming a full bridge, drive control circuits 130a, 130b, PWM carrier wave generation circuit 140, and a switching control circuit 150.

Transistor 110a is connected between a power supply voltage 101 and output node /No, and transistor 110b is connected between power supply voltage 101 and output node No. Transistor 120a is connected between output node /No and a node Ns, and transistor 120b is connected between output node No and node Ns. Transistors 110a and 110b are formed with P-type MOS (Metal Oxide Semiconductor) transistors, while transistors 120a and 120b are formed with N-type MOS transistors. Node Ns is connected to a common voltage 103 via a detection resistance 155 described below.

Drive control circuit 130a controls gate voltages of transistors 110a, 120a based on an indication from switching control circuit 150. Drive control circuit 130b controls gate voltages of transistors 110b, 120b based on an indication from switching control circuit 150. Hereafter, transistors 110a, 120a are also referred to as “left-side bridge”, and transistors 110b, 120b are also referred to as “right-side bridge”.

Thus, on-off switching of transistors 110a, 120a forming the left-side bridge is controlled by drive control circuit 130a, while on-off switching of transistors 110b, 120b forming the right-side bridge is controlled by drive control circuit 130b. A power supply voltage 102 powers drive control circuits 130a, 130b. Power supply voltage 102 may be common to power supply voltage 101.

PWM carrier wave generation circuit 140 generates a carrier wave CWV oscillating in a prescribed cycle. Carrier wave CWV repeats a transition between the high level (also referred to as “H level” hereafter) and the low level (also referred to as “L level” hereafter) in a prescribed cycle.

Switching control circuit 150 includes detection resistance 155 connected between node Ns and common voltage 103, voltage comparators 160a, 160b, and latch circuits 165a, 165b.

A resistance value of detection resistance 155 is Rs. In the following, voltage drop generated at detection resistance 155 is also referred to as a detection voltage V(Rs).

Voltage comparator 160a amplifies a voltage difference between nodes N1a and N2a, and outputs a H level signal or a L level signal corresponding to polarity of the voltage difference. Voltage comparator 160a amplifies a voltage difference between nodes N1b and N2b, and outputs a H level signal or a L level signal corresponding to polarity of the voltage difference.

Each of latch circuits 165a, 165b is set to a reset state if the H level signal is input to a reset terminal R, and is set to a set state if the H level signal is input to a set terminal S when an input to reset terminal R is at the L level.

Carrier wave CWV is input to set terminal S of each latch circuit 165a, 165b. An output signal of voltage comparator 160a is input to reset terminal R of latch circuit 165a, while an output signal of voltage comparator 160b is input to reset terminal R of latch circuit 165b.

Drive control circuits 130a, 130b turn on transistors (P-type MOS transistors) of the upper side (the side of power supply voltage 101) when the corresponding latch circuits 165a, 165b are in the reset state. That is, drive control circuit 130a turns transistor 110a on and turns transistor 120a off when latch circuit 165a is in the reset state. Similarly, drive control circuit 130b turns transistor 110b on and turns transistor 120b off when latch circuit 165b is in the reset state.

On the other hand, drive control circuits 130a, 130b turn on transistors (N-type MOS transistors) of the lower side (the side of common voltage 103) when the corresponding latch circuits 165a, 165b are in the set state. That is, drive control circuit 130a turns transistor 120a on and turns transistor 110a off when latch circuit 165a is in the set state. Similarly, drive control circuit 130b turns transistor 120b on and turns transistor 110b off when latch circuit 165b is in the set state.

Switching control circuit 150 further includes resistance elements 170a and 170b connected between node Ns and nodes N1a and N1b respectively, resistance element 172a connected between node N1a and reference voltage terminal 107, resistance element 172b connected between node N1b and input voltage terminal 106, resistance elements 174a and 174b respectively connected between nodes N2a and N2b and common voltage 103, resistance element 176a connected between node N2a and input voltage terminal 106, and resistance element 176b connected between node N2b and reference voltage terminal 107. A resistance value of each resistance element 170a, 170b, 174a, 174b is R1, and a resistance value of each resistance element 172a, 172b, 176a, 176b is R2.

During a positive direction command time (VIN>VREF), the output of voltage comparator 160a varies corresponding to detection voltage V(Rs), while the output signal of voltage comparator 160b is fixed to the H level. That is, voltage comparator 160a outputs an L-level signal when detection voltage V(Rs) is lower than a prescribed voltage Vr, and outputs an H-level signal when detection voltage V(Rs) is equal to or higher than prescribed voltage Vr. Herein, prescribed voltage Vr is expressed by the following equation (1).

Vr=(R1/R2)·|VIN−VREF| (1)

During a negative direction command time (VIN<VREF), on the other hand, the output of voltage comparator 160b varies corresponding to detection voltage V(Rs), while the output signal of voltage comparator 160a is fixed to the H level. That is, voltage comparator 160b outputs an L-level signal when detection voltage V(Rs) is lower than prescribed voltage Vr, and outputs a H-level signal when detection voltage V(Rs) is higher than prescribed voltage Vr.

Operations of conventional power amplifier 100 will now be described in detail, taking the positive direction command time as an example.

FIG. 7 is a waveform diagram showing operations of conventional power amplifier 100 in the positive direction command time.

Referring to FIG. 7, at a time T1 corresponding to rising (a transition from the L level to the H level) of carrier wave CWV, voltage comparator 160b outputs an H-level signal and voltage comparator 160a outputs an L-level signal in the positive direction command time. Corresponding to this, latch circuit 165a is set to the set state, and transistor 120a is turned on while transistor 110a is turned off in the left-side bridge. On the other hand, transistor 110b is turned on while transistor 120b is turned off in the right-side bridge, because latch circuit 165b is set to the reset state.

With this, load 105 is connected between power supply voltage 101 and common voltage 103, and is biased to a positive direction. Therefore, output current Io increases in the positive direction according to a time constant determined by an inductance value and a resistance value of load 105 and on-resistances of transistors 110b, 120a. Accordingly, detection voltage V(Rs), which is the product of output current Io and resistance value Rs, also increases. In the following, the state wherein load 105 is connected between power supply voltage 101 and common voltage 103 so that power is supplied to load 105 is also referred to as a “power supply mode”.

The power supply mode continues until a time T2, at which time detection voltage V(Rs) reaches prescribed voltage Vr. When detection voltage V(Rs) reaches prescribed voltage Vr at time T2, the output signal of voltage comparator 160a changes from the L level to the H level, while the output signal of voltage comparator 160b remains at the H level. As latch circuit 165a changes from the set state to the reset state in response to this, transistor 120a is turned off and transistor 110a is turned on in the left-side bridge.

With this, both ends (that is, output nodes No, /No) of load 105 are connected to power supply voltage 101 and discharged, and thus output current Io decreases according to the above-mentioned time constant. In the following, the state wherein load 105 is connected to power supply voltage 101 or common voltage 103 so that power is regenerated with load 105 is also referred to as a “resurrection charging current mode”.

Carrier wave CWV falls from the H level to the L level at a time T3. Each latch circuit 165a, 165b, however, remains in the reset state till a time T4 corresponding to the next rising of carrier wave CWV. Therefore, the resurrection charging current mode is maintained from time T2 to T4, and transistors 110a and 120a in the left-side bridge are respectively turned on and off, while transistors 110b and 120b in the right-side bridge are respectively turned on and off.

Such operations are repeated for each cycle of carrier wave CWV, and output current Io as an exponential ripple current is fed to load 105. Smoothing of a ripple of output current lo can be performed by adjusting a frequency of carrier wave CWV and an inductance of load 105.

In the negative direction command time, the transistors are set to be inversely turned on/off in the respective left-side and right-side bridges. As a result, load 105 is biased to the negative direction in the power supply mode, and output current Io flows in a direction opposite to that in the positive direction command time.

In addition, the configuration can be made such that, in the resurrection charging current mode, both transistors in the left-side bridge in the positive direction command time or the right-side bridge in the negative direction command time are turned off, and a resurrection charging current path of output current Io is ensured by an antiparallel diode, which is not shown, included in each transistor.

As shown, detection resistance 155 of output current Io is directly connected to the path of output current Io in series in conventional power amplifier 100. Because the power supply mode and the resurrection charging current mode in the full bridge are switched based on the detection voltage generated at detection resistance 155 arranged as such, linearity can be kept between input voltage VIN and a mean value of output current Io, as expressed in the following equation (2).

Io=(R1/R2)·(1/Rs)·ΔV (2)

(Herein, ΔV=VIN−VREF.)

As a result, power amplifier 100 ensures linearity of transfer conductance, and can operate as a so-called D class amplifier.

In the configuration of conventional power amplifier 100, however, a loss of an output dynamic range corresponding to the product of resistance value Rs of detection resistance 155 and output current Io, and a power loss corresponding to the product of the lost dynamic range and output current Io are caused by output current Io directly flowing through detection resistance 155.

Further, as resistance value Rs must be made smaller considering the above-described losses, resistance value Rs is generally set to the order of 0.1 Ω−1 Ω. As a result, an element having a high power capacity must be applied to detection resistance 155. In addition, control accuracy of output current lo is largely effected by accuracy of resistance value Rs of detection resistance 155. Consequently, because of the need to ensure the absolute value accuracy of resistance value in production and a resistance value variation due to change in temperature, detection resistance 155 is difficult to be embedded in an integrated circuit (IC) on which a power amplifier is mounted, and therefore it has been mounted as an external resistance (external element) to the IC on which the power amplifier is mounted. Such an external small resistance, however, has problems associated with design and cost in substrate mounting, because it becomes larger and more expensive to satisfy the needs for high power capacity and high accuracy of the resistance value.

In addition, in conventional power amplifier 100, controllability decreases in a low output current region to prevent a malfunction at mode switching.

In the positive direction command time, for example, a voltage of output node /No significantly changes in response to transistor 120a in the left-side bridge being turned on in a transition to the power supply mode, resulting in a transient spike current flowing through transistor 120a. Assuming that the voltage changes by an amount ΔVs at output node /No during a time ΔT, the spike current ΔIs is expressed as ΔIs=Co·(ΔVs/ΔT), where Co is an output capacitance of output node /No. If detection voltage V(Rs) at detection resistance 155 momentarily increases due to the spike current, transistor 120a may be turned off and the power supply mode may be ended before output current Io reaches a prescribed level.

Therefore, so-called filting the spike or masking the spike is performed to a sense terminal (node Ns in FIG. 6) to prevent incorrect inversions of outputs of voltage comparators 160a, 160b in an early period of the power supply mode. With this, a transition from the power supply mode to the resurrection charging current mode is forcedly inhibited in a certain period after the power supply mode is started (after current wave CWV rises).

In this configuration, however, a minimum value Imin of controllable output current Io is determined corresponding to length of the certain period and the time constant which depends on the inductance value and the resistance value of load 105 and on-resistances of transistors 110b, 120a. That is, minimum current Imin has a constant value independent of input voltage VIN, and output current Io smaller than minimum current Imin cannot be generated. Consequently, in conventional power amplifier 100, there is a nonlinear portion involving a significant change of the output current in a small output current region. Because of the presence of such a nonlinear portion, its application, for example, to servo control of BTL (Balanced Transformer Less amplifier), in which an accurate current control is needed, is difficult.

The needs of the marketplace to the class D amplifier are growing in recent years, and requests for operability at lower power supply voltage, lower cost and faster PWM carrier frequency are especially strong. With conventional power amplifier 100, however, it was difficult to respond to those requests because of the above-described problems.

### SUMMARY OF THE INVENTION

An object of the present invention is to provide a power amplifier formed with a current chopper-type class D amplifier having high control accuracy and allowing to reduce a cost.

A power amplifier according to the present invention is a power amplifier feeding a direct current corresponding to an input voltage to a load connected between first and second output nodes, and the power amplifier includes first and second transistors electrically connected between a power supply voltage and a common voltage and the first output node respectively, third and fourth transistors electrically connected between the power supply voltage and the common voltage and the second output node respectively, a first mirror transistor connected between one voltage of the power supply voltage and the common voltage and the first output node to form a current mirror with corresponding one of the first and second transistors, a second mirror transistor connected between the one voltage and the second output node to form a current mirror with corresponding one of the third and fourth transistors, a first detection resistance connected in series with the first mirror transistor, a second detection resistance connected in series with the second mirror transistor, a carrier wave generation circuit generating a carrier wave oscillating in a prescribed cycle, a switching control circuit for indicating switching between a power supply mode and a resurrection charging current mode by a bridge formed with the first to fourth transistors to feed the direct current corresponding to a voltage difference between a reference voltage and the input voltage, a first drive control circuit controlling on-off switching of the first and second transistors in response to an indication from the switching control circuit based on a prescribed level transition of the carrier wave, the voltage difference and voltage drop at the second detection resistance, and a second drive control circuit controlling on-off switching of the third and fourth transistors in response to an indication from the switching control circuit based on a prescribed level transition of the carrier wave and voltage drop at the first detection resistance.

Therefore, a primary advantage of the present invention is that, a power amplifier can be constructed which does not cause a dynamic range loss or a power loss due to voltage drop at a detection resistance, because an output current to the load does not directly flow through first and second detection resistances. In addition, an incorrect transition of modes can be prevented without masking the spike or filting the spike, because a transition from the power supply mode to the resurrection charging current mode is controlled by controlling on-off switching of transistors in one side of the bridge based on a passing current in the other side of the bridge. Therefore, the nonlinear portion involving a significant change of the output current in the small output current region can be eliminated to enhance the controllability. In addition, because the detection resistance can be formed with a resistance element having a relatively high resistance and a low power capacity by properly adjusting a current mirror ratio, the detection resistance can be formed within an IC to reduce the cost.

A power amplifier according to another configuration of the present invention is a power amplifier feeding a direct current corresponding to an input voltage to a load connected between first and second output nodes, and the power amplifier includes first and second transistors electrically connected between a power supply voltage and a common voltage and the first output node respectively, third and fourth transistors electrically connected between the power supply voltage and the common voltage and the second output node respectively, a first mirror transistor connected between one voltage of the power supply voltage and the common voltage and the first output node to form a current mirror with corresponding one of the first and second transistors, a second mirror transistor connected between the one voltage and the second output node to form a current mirror with corresponding one of the third and fourth transistors, a first detection resistance connected in series with the first mirror transistor, a second detection resistance connected in series with the second mirror transistor, a carrier wave generation circuit generating a carrier wave oscillating in a prescribed cycle, a switching control circuit for indicating switching between a power supply mode and a resurrection charging current mode by a bridge formed with the first to fourth transistors based on a voltage difference between a reference voltage and the input voltage, a prescribed level transition of the carrier wave, the voltage difference, and voltage drop at the first and second detection resistances, and a drive control circuit controlling on-off switching of the first to fourth transistors in response to an indication from the switching control circuit.

Such a power amplifier does not cause a dynamic range loss or a power loss due to voltage drop at a detection resistance, because an output current to the load does not directly flow through first and second detection resistances. In addition, because the detection resistance can be formed with a resistance element having a relatively high resistance and a low power capacity by properly adjusting a current mirror ratio, the detection resistance can be formed within an IC to reduce the cost.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram showing a configuration of a power amplifier according to a first embodiment of the present invention.

FIG. 2 is a waveform diagram showing an operation example of the power amplifier according to the first embodiment.

FIG. 3 is a circuit diagram showing a configuration of a power amplifier according to a second embodiment.

FIG. 4 is a circuit diagram showing a configuration of a power amplifier according to a third embodiment.

FIG. 5 is a circuit diagram showing a configuration of a power amplifier according to a variation of the third embodiment.

FIG. 6 is a circuit diagram showing a power amplifier configuration of a current chopper-type class D amplifier according to a prior art.

FIG. 7 is a waveform diagram showing an operation example of a conventional power amplifier.

### DESCRIPTION OF THE PREFERRED EMBODIMENTS

Embodiments of the present invention will now be described in detail referring to the drawings. In the drawings, the same characters indicate the same or corresponding portions.

First Embodiment

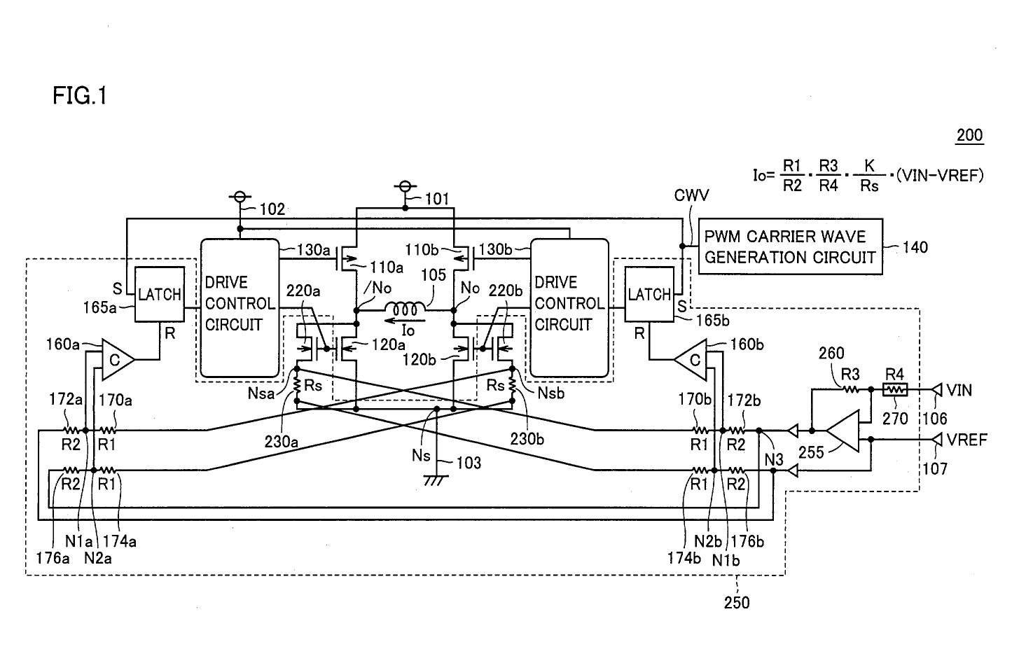

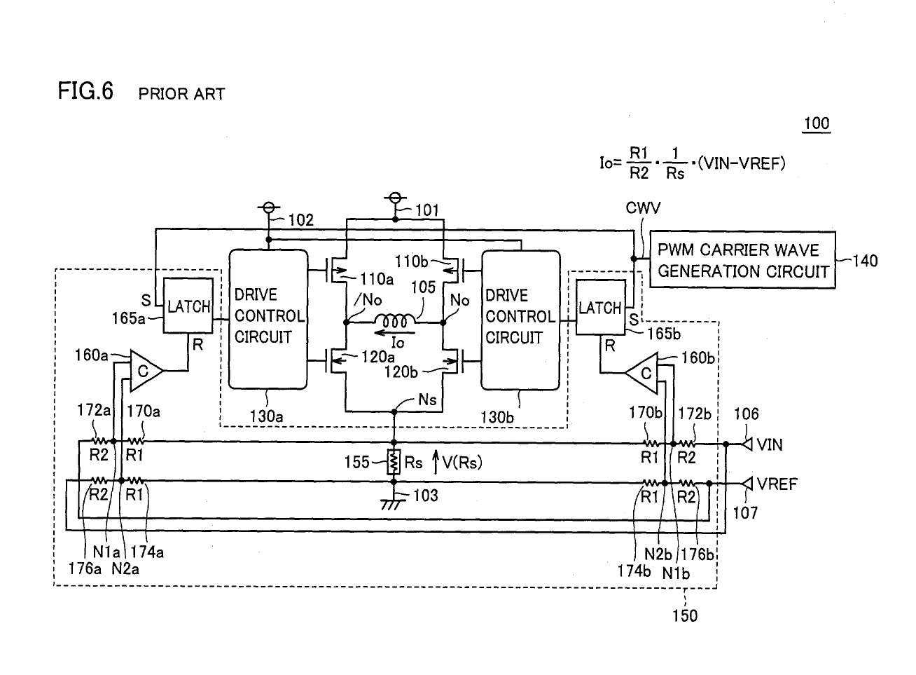

Referring to FIG. 1, a power amplifier 200 according to a first embodiment differs from conventional power amplifier 100 shown in FIG. 6 in a point that, it includes a switching control circuit 250 in place of switching control circuit 150.

Switching control circuit 250 differs from switching control circuit 150 shown in FIG. 6 in a point that, it further includes mirror transistors 220a and 220b provided in parallel with transistors 120a and 120b respectively, detection resistances 230a and 230b provided in place of detection resistance 155, and an operational amplifier 255, a feedback resistance 260 and an input resistance 270 for inverting and amplifying a voltage difference between input voltage VIN and reference voltage VREF. Furthermore, node Ns is directly connected to common voltage 103.

In a configuration according to the first embodiment, common voltage 103 is a ground voltage, and both of input voltage VIN and reference voltage VREF are positive voltages. Power amplifier 200 feeds output current Io having a direction and an amount corresponding to the voltage difference between input voltage VIN and reference voltage VREF to load 105. That is, by providing common voltage 103 and reference voltage VREF individually, the direction of output current Io can be controlled to both of positive and negative directions without using a negative voltage.

Mirror transistor 220a is electrically coupled between output node /No and common voltage 103 to form a current mirror with transistor 120a. Similarly, mirror transistor 220b is electrically coupled between output node No and common voltage 103 to form a current mirror with transistor 120b. Current drivabilities (transistor sizes) of mirror transistors 220a and 220b are 1/K (K: real number where K>1) of that of transistors 120a and 120b.

Detection resistances 230a and 230b are connected in series with respective mirror transistors 220a and 220b. Therefore, currents flowing through mirror transistors 220a and 220b are (1/K) times as large as the currents passing through respective transistors 120a and 120b. Assuming that each resistance value of detection resistances 230a and 230b is Rs, each of detection voltages Va(Rs) and Vb(Rs) generated at detection resistances 230a and 230b due to output current Io passing through transistors 120a and 120b is expressed as Rs·(Io/K).

One of input terminals of operational amplifier 255 is connected to reference voltage terminal 107, while the other of the input terminals is connected to input voltage terminal 106 via input resistance 270. The other input terminal and an output terminal of operational amplifier 255 are connected to each other via feedback resistance 260. A resistance value of feedback resistance 260 is R3, and a resistance value of input resistance 270 is R4. Therefore, a voltage of a node N3 connected to the output terminal of operational amplifier 255 is expressed as—(R3/R4)·(VIN−VREF).

In switching control circuit 150, resistance element 172b is connected between node N3, which corresponds to the output node of operational amplifier 255, and node N1b, while resistance element 176a is connected between node N3 and node N2a. Resistance element 170a is connected between a connection node Nsb of mirror transistor 220b and detection resistance 230b and node N1a. Similarly, resistance element 170b is connected between a connection node Nsa of mirror transistor 220a and detection resistance 230a and node N1b.

Voltage comparator 160a controls a voltage level of a reset terminal of latch circuit 165a corresponding to a voltage of node N3, reference voltage VREF and detection voltage Vb(Rs) at detection resistance 230b. Similarly, voltage comparator 160b controls a voltage level of a reset terminal of latch circuit 165b corresponding to a voltage of node N3, reference voltage VREF and detection voltage Va(Rs) at detection resistance 230a.

Because the voltage difference between input voltage VIN and reference voltage VREF is inverted and amplified at node N3, an output of voltage comparator 160a is fixed to the H level in the positive direction command time (VIN>VREF). On the other hand, in the positive direction command time, voltage comparator 160b outputs an L level signal when detection voltage Va(Rs) of detection resistance 230b is lower than a prescribed voltage Vr′, and outputs an H level signal when detection voltage Va(Rs) is equal to or higher than prescribed voltage Vr′. Herein, the prescribed voltage Vr′ is expressed by the following equation (3).

Vr′=(R1/R2)·(R3/R4)·K·|ΔV|

(Herein, ΔV=VIN−VREF.) (3)

During the negative direction command time (VIN<VREF), on the other hand, an output of voltage comparator 160b is fixed to the H level. In contrast to this, during the negative direction command time (VIN<VREF), voltage comparator 160a outputs an L level signal when detection voltage Va(Rs) of detection resistance 230a is lower than prescribed voltage Vr′, and outputs an H level signal when detection voltage Va(Rs) is equal to or higher than prescribed voltage Vr′.

Though latch circuits 165a, 165b operate as those described referring to FIG. 6, the on-off controlling of transistors 110a, 120a, 110b, 120b by drive control circuits 130a, 130b is set inversely to the configuration shown in FIG. 6. That is, drive control circuits 130a, 130b turn on transistors (P-type MOS transistors) of the upper side (the side of power supply voltage 101) when corresponding latch circuits 165a, 165b are in the set state, and turn on transistors (N-type MOS transistors) of the lower side (the side of common voltage 103) when corresponding latch circuits 165a, 165b are in the reset state.

As other portions of the configuration of power amplifier 200 according to the first embodiment are similar to those of conventional power amplifier 100 shown in FIG. 6, descriptions thereof will not be repeated.

Operations of power amplifier 200 according to the first embodiment will now be described in detail, taking the positive direction command time as an example.

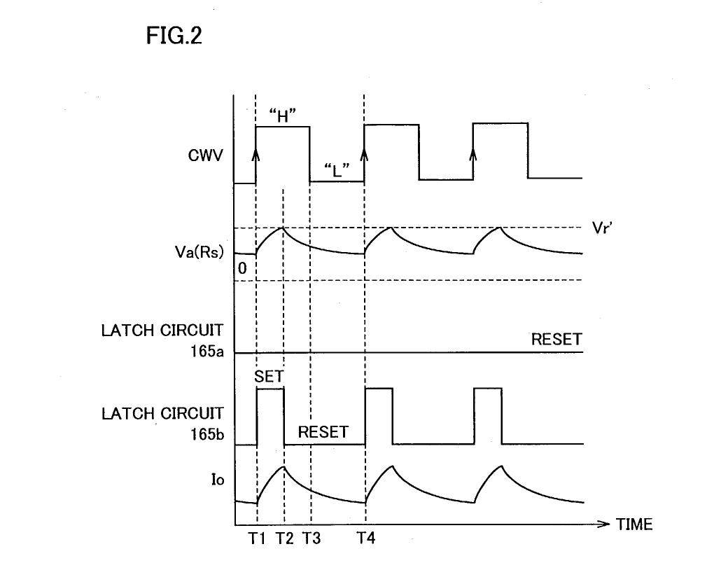

Referring to FIG. 2, at a time T1 corresponding to rising (a transition from the L level to the H level) of carrier wave CWV, voltage comparator 160b outputs an L-level signal and voltage comparator 160a outputs an H-level signal in the positive direction command time. Corresponding to this, latch circuit 165b is set to the set state, and transistor 110b is turned on while transistor 120b is turned off in the right-side bridge. On the other hand, transistor 120a is turned on while transistor 110a is turned off in the left-side bridge, because latch circuit 165a is set to the reset state.

The power supply mode is implemented with this, and load 105 is connected between power supply voltage 101 and common voltage 103, and is biased to a positive direction. Therefore, output current Io increases in a positive direction according to a time constant determined by an inductance value and a resistance value of load 105 and on-resistances of transistors 110b, 120a. Because a current passing through mirror transistor 220a accordingly increases, detection voltage Va(Rs) of detection resistance 230a also increases.

When detection voltage Va(Rs) reaches prescribed voltage Vr′ at time T2, the output signal of voltage comparator 160b changes from the L level to the H level, while the output signal of voltage comparator 160a remains at the H level. As latch circuit 165a changes from the set state to the reset state in response to this, transistor 110a is turned off and transistor 120a is turned on in the left-side bridge.

With this, a transition from the power supply mode to the resurrection charging current mode occurs, and both ends (that is, output nodes No, /No) of load 105 are connected to common voltage 103 and discharged, and thus output current Io decreases according to the above-mentioned time constant. Because each of latch circuits 165a, 165b remains in the reset state till time T4 corresponding to the next rising of carrier wave CWV, the resurrection charging current mode is maintained. That is, transistors 110a and 120a in the left-side bridge are turned off and on respectively, while transistors 110b and 120b in the right-side bridge are turned off and on respectively.

Such operations are repeated for each cycle of carrier wave CWV, and output current Io as an exponential ripple current is supplied to load 105. As described above, smoothing of a ripple of output current Io can be performed by adjusting a frequency of carrier wave CWV and the inductance of load 105.

In the negative direction command time, each of the transistors is set to be inversely turned on/off in the respective left-side and right-side bridges. As a result, load 105 is biased to the negative direction in the power supply mode, and output current Io flows in a direction opposite to that in the positive direction command time.

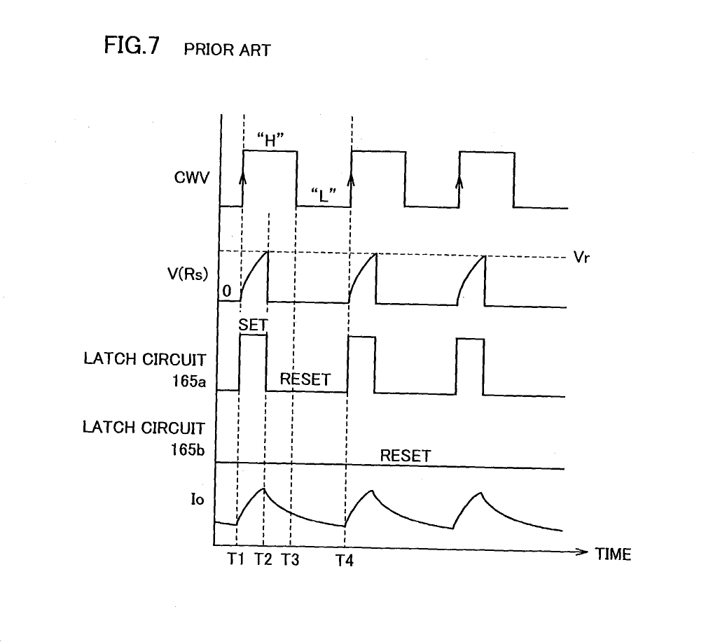

In addition, as described with reference to FIG. 7, the configuration can be made such that, in the resurrection charging current mode, both transistors in the left-side bridge in the positive direction command time or the right-side bridge in the negative direction command time are turned off, and a resurrection charging current path of output current Io is ensured by an antiparallel diode, which is not shown, included in each transistor.

With such switching between the power supply mode and the resurrection charging current mode in the full bridge, power amplifier 200 can operate as a class D amplifier having linearity between input voltage VIN and a mean value of output current Io as expressed with the following equation (4).

Io=(R1/R2)·(R3/R4)·(K/Rs)·ΔV

(Herein, ΔV=VIN−VREF.) (4)

Therefore, in the power amplifier according to the first embodiment, output current lo does not directly passes through detection resistances 230a, 230b, but a current Io/K which is generated by mirror transistors 220a, 220b and which is lower than output current Io passes through detection resistances 230a, 230b. Therefore, the loss of the dynamic range or the power loss is not caused as in the conventional power amplifier.

In addition, though the detection resistance must be made as small as about 0.1 Ω−1 Ω for directly passing output current Io in the conventional power amplifier, resistance value Rs of the detection resistance can be made higher (to about 10 Ω−100 Ω, for example) by properly adjusting the current mirror ratio K in the power amplifier according to the first embodiment. Therefore, detection resistances 230a, 230b can be made within an IC without significantly increasing the cost.

Furthermore, in the transition from the power supply mode to the resurrection charging current mode, a turn-off command of a transistor is generated based on a passing current of another transistor belonging to the other side of the bridge. More specifically, the turn-off command of transistor 110b in the positive direction command time is generated based on a passing current of transistor 120a belonging to the other side of the bridge, and the turn-off command of transistor 110a in the negative direction command time is generated based on a passing current of transistor 120b belonging to the other side of the bridge.

In the positive direction command time, transistor 120b is turned off and transistor 110b is turned on at the transition from the resurrection charging current mode to the power supply mode, and thus the voltage of output node No varies. Because the spike current generated due to such variation in voltage does not appear in a current passing through transistor 120a, a voltage of detection resistance 230a does not momentarily increases, and an incorrect detection of the mode transition is prevented. That is, transistor 110b will not be turned off for the transition from the power supply mode to the resurrection charging current mode when output current Io is not sufficiently fed.

Similarly, in the negative direction command time, though the voltage of output node /No may vary at the transition from the resurrection charging current mode to the power supply mode, such variation in voltage does not appear in a current passing through transistor 120b. Therefore, a voltage of detection resistance 230b does not momentarily increases and an incorrect detection of the mode transition is prevented. That is, transistor 110a will not be turned off for the transition from the power supply mode to the resurrection charging current mode when output current Io is not sufficiently fed.

As a result, in the configuration according to the first embodiment, it is unnecessary to perform masking the spike of filting the spike to the sense terminals (corresponding to nodes Nsa, Nsb in FIG. 1). Therefore, the nonlinear portion involving a significant change of the output current in the small output current region can be eliminated, and controllability can be enhanced.

Further, detection resistances 230a, 230b and feedback resistance 260 are arranged within the same chip (IC) adjacent to each other, and are formed with resistors of the same kind for so-called “pairing”. With this pairing, variations in resistance values in manufacturing and variations in resistance values due to increased temperature of the chip can be cancelled.

That is, by modifying the above-mentioned equation (4), the following equation (5) is obtained.

$$\begin{matrix}{I}_{O} = ( R1 / R2 ) \cdot ( R3 / R4 ) \cdot ( K / Rs ) \cdot Δ V \\ = ( R1 / R2 ) \cdot ( K / R4 ) \cdot ( R3 / Rs ) \cdot Δ V\end{matrix} \\ ( \text{Herein,} Δ V = VIN - VREF . ) \qquad ( 5 )$$

In equation (5), a ratio of resistance values R1, R2 can be made substantially constant by pairing resistance elements 170a-176a and 170b-176b and arranging them within the same IC to eliminate the variation of absolute values in manufacturing and the effect of variation in temperature. In addition, current mirror ratio K is a relatively constant coefficient because it depends on a ratio of transistor sizes of transistors 120a, 120b and mirror transistors 220a, 220b. Resistance value R4 of input resistance 270 can be stabilized by arranging it as an external element of the IC. Therefore, the ratio (K/R4) is also fixedly maintained.

Furthermore, the factor of the ratio (R3/Rs) in equation (5) can also be made constant by pairing detection resistances 230a, 230b and feedback resistance 260. As a result, the power amplifier can be constructed as a class D amplifier which ensures linearity of transfer conductance by suppressing a degradation of accuracy of an input-output gain even when detection resistances 230a, 230b are provided as internal elements within the IC (semiconductor integrated circuit) rather than as external resistance elements which are disadvantageous with respect to the cost.

In addition, as can be understood from equations (4), (5), fine adjustment of the input-output gain (Io/VIN) of power amplifier 200 from the outside becomes possible with input resistance 270 provided as an external element. In contrast to detection resistance 155 shown in FIG. 6, input resistance 270 can be implemented with a low cost because it may not use a resistance element having a small resistance and a high power capacity, but can be formed with a relatively high resistance and a low power capacity. Other circuit elements of power amplifier 200 including detection resistances 230a, 230b are arranged on the semiconductor integrated circuit (IC).

As shown in FIG. 1, voltages between the gates and sources do not completely coincide between transistor 120a and mirror transistor 220a, and between transistor 120b and mirror transistor 220b. As a result, linearity of the input-output gain may be degraded in a region having large output current Io because of phenomena such as an increase in detection voltage V (Rs) due to reduction of impedances of mirror transistors 220a, 220b corresponding to increases of gate voltages of transistors 120a, 120b, and an increase in current mirror ratio K due to reduction of impedances of mirror transistors 220a, 220b corresponding to an increase of output current Io. This problem, however, can be solved to a usable extent by stabilizing gate voltages of transistors 120a, 120b with drive control circuits 130a, 130b.

Second Embodiment

In a second embodiment, a configuration of a power amplifier which enhances controllability by further suppressing the risk of malfunction will be described.

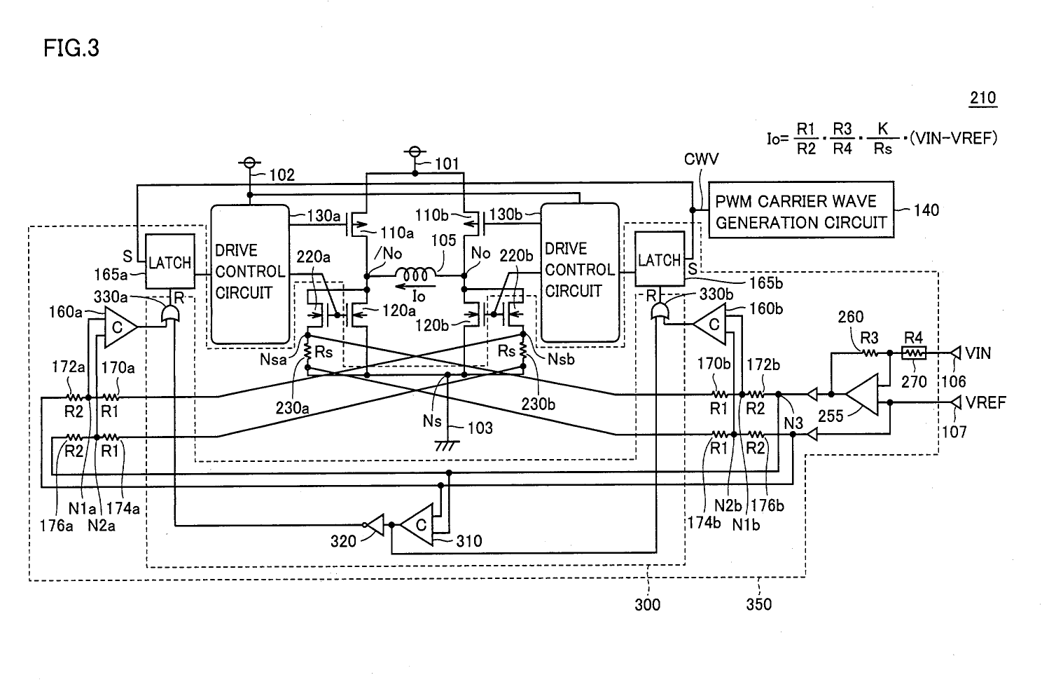

Referring to FIG. 3, a power amplifier 210 according to the second embodiment differs from power amplifier 200 according to the first embodiment shown in FIG. 1 in that, it includes a switching control circuit 350 in place of switching control circuit 250. In addition to the configuration of switching control circuit 250 as shown in FIG. 1, switching control circuit 350 further includes a switching fixing circuit 300.

Switching fixing circuit 300 has a voltage comparator 310 outputting a voltage difference between node N3 and reference voltage VREF, an inverter 320 inverting an output of voltage comparator 310, a logic gate 330a, and a logic gate 330b. Logic gate 330a inputs a result of an OR operation of output signals of inverter 320 and voltage comparator 160a to reset terminal R of latch circuit 165a. Similarly, logic gate 330b inputs a result of an OR operation of output signals of voltage comparator 310 and voltage comparator 160b to reset terminal R of latch circuit 165b.

The output of voltage comparator 310 is fixed to the L level in the positive direction command time (VIN>VREF), and is fixed to the H level in the negative direction command time (VIN<VREF).

As can be understood from the description above, the switching state of one side of the bridge must be fixed in the respective positive direction command time and negative direction command time in power amplifiers 200, 210. More specifically, transistor 110a must be maintained in an off-state and transistor 120a must be maintained in an on-state in the left-side bridge in the positive direction command time. That is, latch circuit 165a must be kept in the reset state. Similarly, transistor 110b must be maintained in an off-state and transistor 120b must be maintained in an on-state in the right-side bridge in the negative direction command time. That is, latch circuit 165b must be kept in the reset state.

As described above, however, because the voltage of output node No may vary at the transition from the resurrection charging current mode to the power supply mode in the positive direction command time, detection voltage Vb(Rs) of detection resistance 230b may increase with the effect of the spike current flowing through transistor 120b, and the output of voltage comparator 160a may momentarily change from the H level to the L level to incorrectly change latch circuit 165a to the set state. With such a phenomenon, on-state and off-state of transistors 110a and 120a are exchanged, and thus noise such as a new spike voltage may be generated in each portion to make the circuit operation unstable.

In the negative direction command time, on the other hand, detection voltage Va(Rs) of detection resistance 230a may increase with an undesirable effect of a variation in voltage generated at output node /No, and latch circuit 165b which should be held in the reset state may change to the set state to make the circuit operation unstable.

In the power amplifier according to the second embodiment, the output signal of inverter 320 is fixed to the H level in the positive direction command time, and therefore the output of logic gate 330a is also fixed to the H level. Thus, latch circuit 165a does not incorrectly change to the set state if the detection voltage at detection resistance 230b momentarily increases due to the spike current or the like. On the other hand, as the output signal of voltage comparator 310 is fixed to the L level, the input signal to reset terminal R of latch circuit 165b is set as in power amplifier 200 shown in FIG. 1.

In the negative direction command time, the output signal of voltage comparator 310 is fixed to the H level, and therefore the output of logic gate 330b is also fixed to the H level. Thus, latch circuit 165b does not incorrectly change to the set state if the detection voltage at detection resistance 230a momentarily increases due to the spike current or the like. On the other hand, as the output signal of inverter 320 is fixed to the L level, the input signal to reset terminal R of latch circuit 165a is set as in power amplifier 200 shown in FIG. 1.

In addition to the effect obtained with the voltage amplifier according to the first embodiment, the voltage amplifier according to the second embodiment can stabilize the circuit operation by securely fixing the operations of the left-side bridge in the positive direction command time and the right-side bridge in the negative direction command time.

Third Embodiment

A variation of a circuit configuration of power amplifier 200 shown in the first embodiment will be described in a third embodiment.

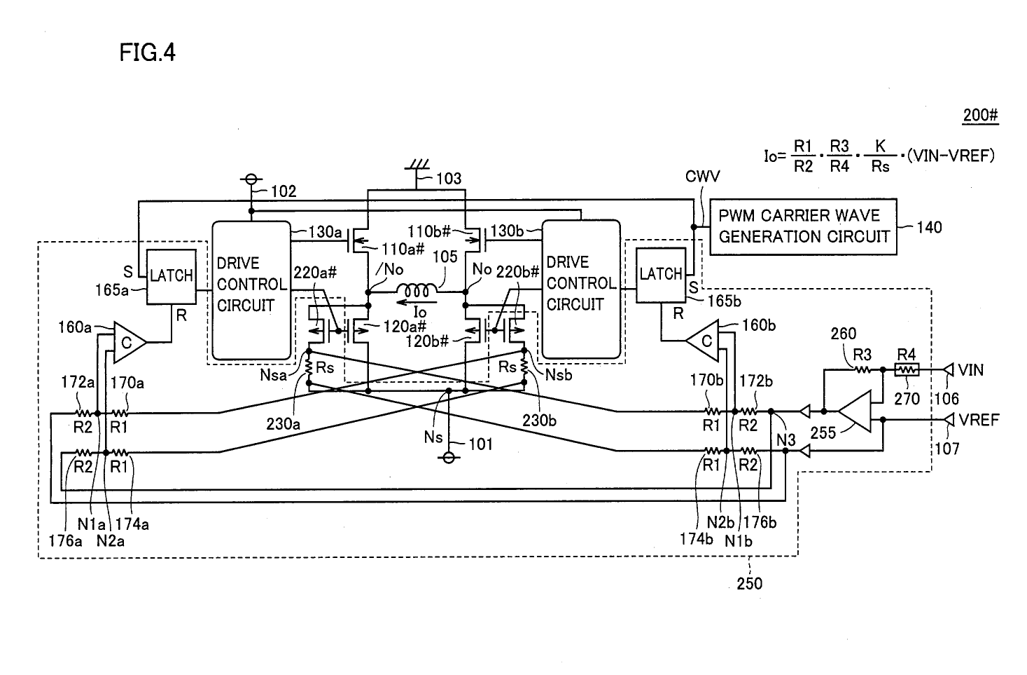

Referring to FIG. 4, a power amplifier 200# according to the third embodiment differs from power amplifier 200 shown in FIG. 1 in that, it includes transistors 110a#, 110b#, 120a#, 120b# arranged in place of transistors 110a, 110b, 120a, 120b, and that the relations of the connections between the full bridge formed with these transistors and power supply voltage 101 and common voltage 103 are inverted.

Each of transistors 110a# and 110b# coupled to common voltage 103 is formed with an N-type MOS transistor, while each of transistors 120a# and 120b# coupled to power supply voltage 101 is formed with a P-type MOS transistor. In addition, mirror transistors 220a# and 220b# formed with P-type MOS transistors are provided in place of mirror transistors 220a and 220b.

Mirror transistors 220a# and 220b# are electrically coupled between nodes /No and No and power supply voltage 101, respectively. Similar to the configuration shown in FIG. 1, detection resistances 230a and 230b are connected to respective mirror transistors 220a# and 220b# in series. As configurations and operations of other portions of power amplifier 200# are similar to those of power amplifier 200 shown in FIG. 1, detailed descriptions thereof will not be repeated.

With such a configuration, wherein mirror transistors are provided for transistors 120a#, 120b# (P-type MOS transistors) on the side of power supply voltage 101, similar effect as with the power amplifier according to the first embodiment can be obtained.

Variation of Third Embodiment

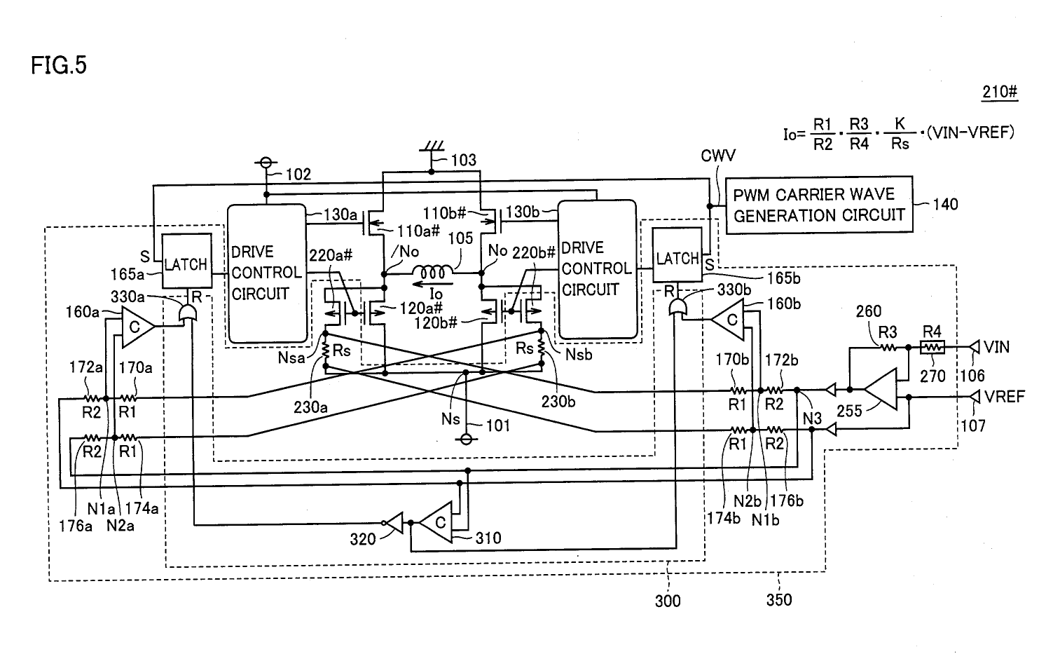

Referring to FIG. 5, a power amplifier 210# according to a variation of the third embodiment differs from power amplifier 210 according to the second embodiment shown in FIG. 3 in that, it includes transistors 110a#, 110b#, 120a#, 120b# arranged in place of transistors 110a, 110b, 120a, 120b, and that the relations of the connections between the full bridge formed with these transistors and power supply voltage 101 and common voltage 103 are inverted, and that mirror transistors 220a# and 220b# are provided in place of mirror transistors 220a and 220b.

Because these differences are similar to those between FIGS. 1 and 4, detailed descriptions thereof will not be repeated. In addition, because configurations and operations of other portions of power amplifier 210# are similar to those of power amplifier 210 shown in FIG. 3, detailed descriptions thereof will not be repeated.

With such a configuration, wherein mirror transistors are provided for transistors 120a#, 120b# (P-type MOS transistors) on the side of power supply voltage 101, similar effect as with the power amplifier according to the second embodiment can be obtained.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A power amplifier feeding a direct current corresponding to an input voltage to a load connected between first and second output nodes, comprising:
first and second transistors electrically connected between a power supply voltage and a common voltage and said first output node respectively;
third and fourth transistors electrically connected between said power supply voltage and said common voltage and said second output node respectively;
a first mirror transistor connected between one voltage of said power supply voltage and said common voltage and said first output node to form a current mirror with corresponding one of said first and second transistors;
a second mirror transistor connected between said one voltage and said second output node to form a current mirror with corresponding one of said third and fourth transistors;
a first detection resistance connected in series with said first mirror transistor;
a second detection resistance connected in series with said second mirror transistor;
a carrier wave generation circuit generating a carrier wave oscillating in a prescribed cycle;
a switching control circuit for indicating switching between a power supply mode and a resurrection charging current mode by a bridge formed with said first to fourth transistors to feed said direct current corresponding to a voltage difference between a reference voltage and said input voltage;
a first drive control circuit controlling on-off switching of said first and second transistors in response to an indication from said switching control circuit based on a prescribed level transition of said carrier wave, said voltage difference and voltage drop at said second detection resistance; and
a second drive control circuit controlling on-off switching of said third and fourth transistors in response to an indication from said switching control circuit based on said prescribed level transition of said carrier wave, said voltage difference and voltage drop at said first detection resistance.

2. The power amplifier according to claim 1, wherein
said switching control circuit indicates a transition from said resurrection charging current mode to said power supply mode in response to said prescribed level transition of said carrier wave, and indicates a transition from said power supply mode to said resurrection charging current mode when said voltage drop in one of said first and second detection resistances exceeds a prescribed voltage.

3. The power amplifier according to claim 1, wherein
one of said first and second drive control circuits corresponding to polarity of said voltage difference turns on one of corresponding transistors connected to the other voltage of said power supply voltage and said common voltage in said power supply mode, and turns off in said resurrection charging current mode.

4. The power amplifier according to claim 3, wherein
said switching control circuit further includes a switching fixing circuit for forcedly fixing on/off state of corresponding transistors in the other of said first and second drive control circuit corresponding to said polarity, and
said switching fixing circuit fixedly turns on and turns off one of said corresponding transistors connected to said one voltage and the other of said corresponding transistors connected to said the other voltage respectively, independent of the voltage drop at said first or second detection resistance.

5. The power amplifier according to claim 1, wherein
said switching control circuit further includes a voltage amplifier inverting and amplifying said voltage difference according to a ratio between a feedback resistance and an input resistance and outputting the result,
said first drive control circuit controls on-off switching of said first and second transistors in response to the indication from said switching control circuit corresponding to said prescribed level transition of said carrier wave, said voltage drop at said second detection resistance and an output voltage of said voltage amplifier,
said second drive control circuit controls on-off switching of said third and fourth transistors in response to the indication from said switching control circuit corresponding to said prescribed level transition of said carrier wave, said voltage drop at said first detection resistance and said output voltage of said voltage amplifier, and
said first and second detection resistances and said feedback resistance are designed with resistors of the same kind and arranged adjacent to each other.

6. The power amplifier according to claim 5, wherein
said power amplifier is mounted on a semiconductor integrated circuit, and
said input resistance is provided outside of said semiconductor integrated circuit.

7. A power amplifier feeding a direct current corresponding to an input voltage to a load connected between first and second output nodes, comprising:
first and second transistors electrically connected between a power supply voltage and a common voltage and said first output node respectively;
third and fourth transistors electrically connected between said power supply voltage and said common voltage and said second output node respectively;
a first mirror transistor connected between one voltage of said power supply voltage and said common voltage and said first output node to form a current mirror with corresponding one of said first and second transistors;
a second mirror transistor connected between said one voltage and said second output node to form a current mirror with corresponding one of said third and fourth transistors;
a first detection resistance connected in series with said first mirror transistor;
a second detection resistance connected in series with said second mirror transistor;
a carrier wave generation circuit generating a carrier wave oscillating in a prescribed cycle;
a switching control circuit for indicating switching between a power supply mode and a resurrection charging current mode by a bridge formed with said first to fourth transistors based on a voltage difference between a reference voltage and said input voltage, a prescribed level transition of said carrier wave, said voltage difference, and voltage drop at said first and second detection resistances; and
a drive control circuit controlling on-off switching of said first to fourth transistors in response to an indication from said switching control circuit.

8. The power amplifier according to claim 7, wherein
said switching control circuit further includes a voltage amplifier inverting and amplifying said voltage difference according to a ratio between a feedback resistance and an input resistance and outputting the result,
said switching control circuit indicates switching between said power supply mode and said resurrection charging current mode corresponding to said prescribed level transition of said carrier wave, said voltage drop at said first and second detection resistances and an output voltage of said voltage amplifier, and
said first and second detection resistances and said feedback resistance are designed with resistors of the same kind and arranged adjacent to each other.
